(19) United States
(12) Patent Application Publication
(10) Pub. No.: US 2001/0029091 A1
(43) Pub. Date: Oct. 11, 2001

(54) METHOD FOR MANUFACTURING AN ELECTRONIC DEVICE COMPRISING AN ORGANIC- CONTAINING MATERIAL

(75) Inventors: PETRUS M. MEIJER, EINDHOVEN (NL); BARTHOLOME S. MANDERS, EINDHOVEN (NL); HERBERT LIFKA, EINDHOVEN (NL)

Correspondence Address: CORPORATE PATENT COUNSEL, US PHILIPS CORPORATION, 580 WHITE PLAINS ROAD, TARRYTOWN, NY, 10591

(73) Assignee: U.S. PHILIPS CORPORATION

(21) Appl. No.: 09/175,247

(22) Filed: Oct. 20, 1998

(30) Foreign Application Priority Data
Apr. 17, 1998 (EP) 98201241.1

(51) Int. Cl. H01L 51/40

(52) U.S. Cl. 438/584; 438/689

(57) ABSTRACT

A method for manufacturing an electronic device comprising an organic-containing material (3) comprises the steps of:

covering the organic-containing material (3) with a SiO₂ layer (4),

applying a SiN layer (5) to the SiO₂ layer (4),

applying and patterning a resist layer (6),

etching through the SiN layer (5) by means of an etch process wherein SiN is etched faster than SiO₂,

removing the resist (6),

etching through the SiO₂ layer (4) by means of an etch process wherein SiO₂ is etched faster than SiN,

removing the SiN layer (5),

etching the organic dielectric material (3) using the SiO₂ layer (4) as a mask.

The invention relates to a method for manufacturing an electronic device comprising an organic-containing material, said method comprising the steps of:

covering the organic-containing material with a layer of a first inorganic material,

applying a layer of a second inorganic material which is different from the first inorganic material,

providing a resist layer with a pattern of openings,

etching through the layer of the second inorganic material at the location of the openings,

etching through the layer of the first inorganic material at the location of the openings and etching the organic-containing material.

Such a method is known from EP-A-0 680 085. The known method is used to form an electrical connection between two conductors in different layers in a semiconductor device through an organic-containing dielectric material. In one embodiment of the known method, a conductive layer is deposited on an insulating layer and the conductive layer is patterned. A layer of parylene is deposited on and between the conductors provided in accordance with a pattern, after which the parylene layer is planarized by chemico-mechanical polishing. A layer of SiO₂ is applied onto the parylene layer and the SiO₂ layer is covered with a SiN layer. By using a resist mask, a via is etched through the SiN layer, the SiO₂ layer and the parylene layer. A passivation layer is applied to cover the parylene at the side walls of the via. In order to be able to contact the conductor at the bottom of the via, the passivation layer is removed from the bottom of the via by anisotropic etching. The SiN layer is applied to prevent etching of the SiO₂ layer during this anisotropic etching operation. A conductive layer is applied so as to fill the via, thereby forming an electrical connection to the conductor at the bottom of the via. Finally, the conductive layer is patterned.

A disadvantage of the known method is that it is difficult to control the dimensions of the via.

It is an object of the invention to provide a method for manufacturing an electronic device comprising an organic-containing material, which results in well-defined dimensions of the structure in the organic-containing material. To this end, the method in accordance with the invention is characterised in that

the layer of the second inorganic material is subjected to an etch process wherein the second inorganic material is etched faster than the first inorganic material,

the resist layer is removed in between the processes of etching through the layer of the second inorganic material and etching through the layer of the first inorganic material, and

the layer of the first inorganic material is subjected to an etch process wherein the first inorganic material is etched faster than the second inorganic material.

A resist also contains organic material and it has been found that etch processes for removing resist also etch away the organic-containing material. In the known method, the organic-containing material is exposed during removal of the resist. Hence, the organic-containing material and the resist are etched at the same time. During the etch process, a transition from etching resist to not etching resist occurs the moment the resist is completely removed. This transition causes a change of the etch conditions, so that the critical dimension control of the etch process is adversely affected. By using the method according to the invention, the organic-containing material is not exposed during removal of the resist. Because the layer of the second inorganic material is etched in an etch process wherein the second inorganic material is etched faster than the first inorganic material, the layer of the first inorganic material is kept in place without the timing of the etch process for the layer of the second inorganic material being critical. Because the layer of the first inorganic material is kept in place, the resist is removed without affecting the layer of organic-containing material. After removing the resist, the layer of the first inorganic material is etched by using the layer of the second inorganic material as a mask. Finally, the organic-containing layer is etched. During this last etch process, a transition as described above does not occur. As a result, the method in accordance with the invention results in better defined dimensions of the structure in the organic-containing material than in the known method.

In an embodiment of the method in accordance with the invention, the resist is removed by isotropic etching. Due to the measures in accordance with the invention, the organic-containing material is wholly covered by the layer of the first inorganic material during removal of the resist mask. As a result the resist mask can be removed by isotropic etching, for example in an oxygen plasma, without any etching of the organic-containing material. Since isotropic etching to remove the resist is very reliable, the yield of this embodiment of the method according to the invention can be very high.

The measure as defined in dependent claim 3 has the advantage that the method is suitable for reducing the capacitance between conductors in a semiconductor device.

The method according to the invention can also be used to form a via in the organic-containing material. In that case a conductor has to contact the bottom of the via. Contamination of the bottom of the via may result in an increased contact resistance. The measure as defined in dependent claim 4 has the advantage that the bottom of the via is still covered with the organic-containing material during removal of the layer of the second inorganic material. In this way contamination of the bottom of the via in the organic-containing material during removal of the second inorganic material is counteracted.

The measure as defined in dependent claim 5 has the advantage that conductor paths can be formed with a high density. This method is known as the “damascene process”. The conductive material outside the trenches is removed, for example, by chemico-mechanical processing.

The measure as defined in dependent claim 6 has the advantage that contamination of the bottom of the trenches during removal of the first inorganic material and/or the second inorganic material is counteracted because contact between the conductive material in the trenches and the bottom of the trenches is made before removal of the inorganic layer or layers.

The measure as defined in dependent claim 7 has the advantage that only one process step is required to remove the conductive material outside the trenches and the layer or layers of inorganic material. Moreover, it has been found that an organic-containing material is removed at a much lower rate during chemico-mechanical polishing than conductive and inorganic materials so that the layer of organic-containing material can serve as a stop layer for the chemico-mechanical polishing operation.

The method in accordance with the invention is also very suitable for patterning an organic-containing material that has electroluminescent properties such as, for example, poly-(2-metoxy-5-(3,7-dimethyloctyloxy)-1,4-chloromethylbenzene). In that case the first inorganic material may be aluminium, which may be etched in a chlorine-based plasma and the second inorganic material may be silicon nitride which is etched in a fluorine-based plasma.

These and other aspects of the invention will be apparent from and elucidated with reference to the embodiments described hereafter.

In the drawings:

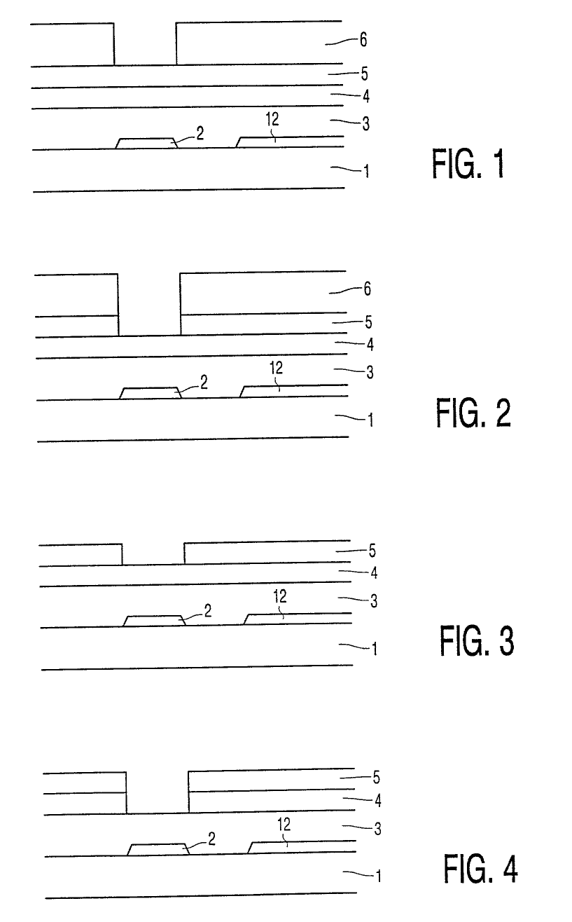

FIG. 1 shows a diagrammatic cross-section of a substrate 1 with a stack of layers comprising a layer 3 of an organic-containing material, a layer 4 of a first inorganic material, a layer 5 of a second inorganic material and a patterned resist layer 6, FIG. 2 shows a diagrammatic cross-section of the inventive stack of layers shown in FIG. 1 of the invention after etching the layer 5 of the second inorganic material, FIG. 3 shows a diagrammatic cross-section of the stack of layers shown in FIG. 2 after the resist layer 6 has been removed.

FIG. 4 shows a diagrammatic cross-section of the stack of layers shown in FIG. 3 after etching the layer 4 of the first inorganic material,

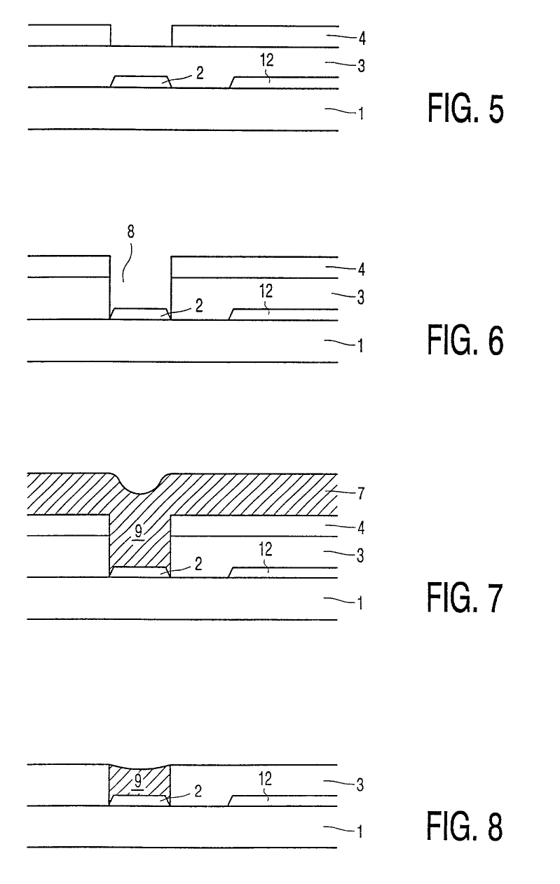

FIG. 5 shows a diagrammatic cross-section of the stack of layers shown in FIG. 4 after removal of the layer 5 of the second inorganic material according to a first embodiment of the invention,

FIG. 6 shows a diagrammatic cross-section of the stack of layers shown in FIG. 5 after etching the layer 3 of the organic-containing material according to the first embodiment of the invention,

FIG. 7 shows a diagrammatic cross-section of the stack of layers shown in FIG. 6 after deposition of a first layer of a conductive material 7 according to the first embodiment of the invention,

FIG. 8 shows a diagrammatic cross-section of the stack of layers shown in FIG. 7 after removal of part of the conductive material 7 and the layer 4 of the first inorganic material,

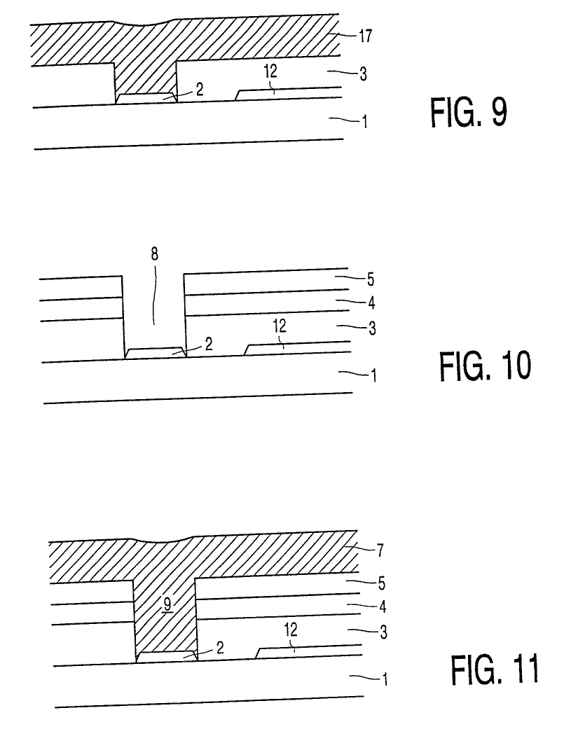

FIG. 9 shows a diagrammatic cross-section of the stack of layers shown in FIG. 8 after applying a second layer of conductive material 17,

FIG. 10 shows a diagrammatic cross-section of the stack of layers shown in FIG. 4 after etching the layer of the organic-containing material 3 according to a second embodiment of the invention, and

FIG. 11 shows a diagrammatic cross-section of the stack of layers shown in FIG. 10 after deposition of a conductive material 7 according to the second embodiment of the invention.

FIGS. 1 to 9 represent diagrammatic cross-sections of a number of intermediate results during the operation of a first embodiment of the method for manufacturing an electronic device comprising an organic-containing material according to the invention.

The situation shown in FIG. 1 is obtained by spinning a layer 3 of organic-containing material onto a silicon substrate 1 covered with SiO₂. In this example it is a material with a low dielectric constant named “SILK©” which is marketed by Dow Chemical from Midland, Mich., USA. A pattern of conductors 2 and 12 may be present on the substrate 1 and these conductors 2 and 12 may be connected to a semiconductor device formed in the substrate 1. The SILK layer 3 is covered with a layer 4 of a first inorganic material, in this case SiO₂, which is applied by PE-CVD at low temperatures, i.e. <450 degrees Celsius. Optionally, an adhesive layer (not shown) may be applied to the layer 3 of organic-containing material before the layer 4 of the first inorganic material is applied. A layer 5 of a second inorganic material, in this example SiN, is applied to the SiO₂ layer by PE-CVD at low temperatures, i.e. <450 degrees Celsius. The second inorganic material must be different from the first inorganic material, so that these materials can be selectively etched. A resist layer 6 is applied to the SiN layer 5 and the resist layer 6 is provided with a pattern of openings by means of known techniques.

The situation shown in FIG. 2 is obtained by etching the SiN layer 5 is an etch process wherein SiN is etched faster than SiO₂, for example anisotropic etching with CH₃F— gas. As a result, SiN can be locally removed while SiO₂ functions as a stop layer, so that the timing of the etching process is not critical.

The situation shown in FIG. 3 is obtained by removing the resist layer 6 by an etch process wherein the resist is etched faster than SiN and SiO₂, for example an isotropic etch process with oxygen-based chemicals. As a result the resist can be removed without critical timing because the SiN layer 5 and the SiO₂ layer 4 are hardly affected. The situation shown in FIG. 4 is obtained by etching the SiO₂ layer 4 in an etch process wherein SiO₂ is etched faster than SiN, for example an anisotropic etch process with CO/C₄F₈. As a result the SiO₂ can be locally removed while the SiN layer 5 functions as a mask.

The situation shown in FIG. 5 is obtained with a process wherein the SiN layer 5 is removed faster than the SiO₂ layer 4, for example by etching with a phosphoric acid. As a result the SiN layer 5 can be removed while the SiO₂ layer 4 functions as a stop layer so that the timing of this step is not critical.

A via 8 is formed, as shown in FIG. 6, by etching the SILK layer 3 in an etch process wherein SILK is etched faster than SiO₂, for example a HBr/O₂ etch process.

A plug 9 as shown in FIG. 7 is obtained by deposition of a conductive material 7, for example aluminium, onto the patterned organic-containing material 3 by a PVD or a CVD process.

The situation shown in FIG. 8 is obtained by partly removing the conductive material 7 and the SiO₂ layer 4 until the SILK layer 3 is exposed. This can for example be done by chemico-mechanical polishing with a slurry like SS-EP-A-5600, which is marketed by Cabot, 5080 Robert J. Mathews Parkway, El Dorado Hills, USA.

The situation shown in FIG. 9 is obtained by deposition of a conductive layer 17, for example also of aluminium, onto the patterned organic-containing material 3 by a PVD or a CVD process. The conductive layer 17 may be patterned by known techniques to form conductor paths. The conductor 12 and the conductive layer 17 are separated by the layer of SILK only because the SiN layer 5 and the SiO₂ layer 4 have been removed in previous steps. Because SILK has a lower dielectric constant than SiO₂, the capacitance between these conductors 12 and 17 is lower when the space between these conductors 12 and 17 is completely filled with SILK. Hence, removal of the SiN layer and the SiO₂ layer results in a lower capacitance over a certain desired distance between the conductors 12 and 17.

FIGS. 10 and 11 represent diagrammatic cross-sections of two intermediate results during the operation of a second embodiment of the method for manufacturing an electronic device comprising an organic-containing material according to the invention. In this second embodiment the SiN layer 5 is not removed before a layer of conductive material 7 has been applied.

Starting from the situation shown in FIG. 4 the situation shown in FIG. 10 is obtained by etching the SILK layer 3 in an etch process wherein SILK is etched faster than SiN, for example HBr/O₂ or SO₂/O₂.

The situation shown in FIG. 11 is obtained by depositing a conductive material 7, for example aluminium, onto the patterned organic-containing material by a PVD or a CVD process. After chemico-mechanical polishing, a situation as shown in FIG. 8 is obtained.

Starting from the situation shown in FIG. 11, the situation shown in FIG. 8 is obtained by partly removing the conductive material 6, the SiN layer and the SiO₂ layer until the SILK layer 3 is exposed. This can for example be done by chemico-mechanical polishing with a slurry like SS-EP-A-5600. Further steps of the second embodiment of the method according to the invention are the same as those described with reference to FIG. 9.

In a third embodiment of the invention, the via 8 shown in FIG. 6 and FIG. 10 is replaced by a trench which extends in a direction perpendicular to the plane of the drawing. In this third embodiment the plug 9 shown in FIGS. 7 and 11 forms a conductor which extends in a direction perpendicular to the plane of the drawing. This method of forming conductor paths is known as the damascene process.

The invention has been elucidated by means of examples in which the first inorganic material is SiO₂ and the second inorganic material is SiN. Other combinations are shown in the following table:

TABLE

| First | Second | | |
|---|---|---|---|
| inorganic | inorganic | Etch process for First | Etch process for Second |
| material | material | inorganic material | inorganic material |
| SiN | SiO₂ | CH₃F | CO/C₄F₈ |
| SiO₂ | TiN | CF₄ | chlorine-based |
| | | | e.g. Cl₂ |
| SiO₂ | a-Si | fluorine-based | chlorine-based |
| SiO₂ | Ti | fluorine-based | chlorine-based |
| SiO₂ | Al | fluorine-based | chlorine-based |
| Al | W | fluorine-based | chlorine-based |
| Al | SiN | chlorine-based | fluorine-based |
| SiO₂ | TaN | fluorine-based | chlorine-based |

It is to be noted that the invention is not limited to the embodiments described above. In addition to SILK©, other organic-containing materials such as Parylene© and Teflon©-like materials can be structured using the method according to the invention. The resist can be a photoresist, an e-beam resist or an x-ray resist. The basic requirement is that the first inorganic material and the second inorganic material are etched selectively as defined in claim 1.

1. A method for manufacturing an electronic device comprising an organic-containing material, said method comprising the steps of:
covering the organic-containing material with a layer of a first inorganic material,
applying a layer of a second inorganic material which is different from the first inorganic material,
providing a resist layer with a pattern of openings,
etching through the layer of the second inorganic material at the location of the openings,
etching through the layer of the first inorganic material at the location of the openings, and
etching the organic-containing material at the location of the openings, characterised in that
the layer of the second inorganic material is subjected to an etch process wherein the second inorganic material is etched faster than the first inorganic material,
the resist layer is removed in between the processes of etching through the layer of the second inorganic material and etching through the layer of the first inorganic material, and
the layer of the first inorganic material is subjected to an etch process wherein the first inorganic material is etched faster than the second inorganic material.

2. A method as claimed in claim 1, characterised in that the resist layer is removed by an isotropic etching.

3. A method as claimed in claim 1, characterised in that the organic-containing material is a dielectric material with a low dielectric constant.

4. A method as claimed in claim 1, characterised in that the layer of the second inorganic material is removed before the organic-containing material is etched.

5. A method as claimed in claim 1, characterised in that trenches are formed in the organic-containing material, a conductive material is deposited both inside and outside the trenches and the conductive material outside the trenches is removed.

6. A method as claimed in claim 5, characterised in that the layer of the second inorganic material and/or the layer of the first inorganic material is removed after the conductive material has been applied and partly removed.

7. A method as claimed in claim 5 or 6, characterised in that the conductive material outside the trenches and the layer or layers of inorganic material are removed by chemico-mechanical polishing.

8. A method as claimed in claim 1, characterised in that the organic-containing material has electroluminescent properties.
